(19) United States
(12) Patent Application Publication
(10) Pub. No.: US 2024/0313709 A1
(43) Pub. Date: Sep. 19, 2024

(54) AMPLIFIER ERROR CORRECTION CIRCUIT

(71) Applicant: Telefonaktiebolaget LM Ericsson (PUBL), Stockholm (SE)

(72) Inventors: Ling Qin, CHENGDU (CN); Yonghai Jin, Beijing (CN); Richard Hellberg, HUDDINGE (SE)

(21) Appl. No.: 18/578,408

(22) PCT Filed: Jul. 15, 2021
(86) PCT No.: PCT/CN2021/106386

§ 371 Date: Jan. 11, 2024

(51) Int. Cl. H03F 1/32; H03F 3/24

(52) U.S. Cl. CPC H03F 1/32; H03F 3/245; H03F 2200/451

(57) ABSTRACT

Amplifier error correction circuits are disclosed, including in an example an amplifier error correction circuit. The amplifier error correction circuit comprises a plurality of sub-amplifiers, a first input adapted to receive an output signal of an amplifier circuit, and an error signal input adapted to receive an error signal indicative of an error in the output signal of the amplifier circuit. The amplifier error correction circuit also comprises a sub-amplifier input signal preparation circuit adapted to provide a respective portion of the error signal to each of the sub-amplifiers, and an output signal combining circuit adapted to combine outputs of the sub-amplifiers with the output signal of the amplifier circuit and to provide a combined signal to an output of the amplifier correction circuit. At least one of the sub-amplifiers comprises a cascode amplifier.

### TECHNICAL FIELD

Examples of the present disclosure relate to amplifier error correction circuits.

### BACKGROUND

Power amplifiers are widely used for example in radio base stations and user equipments (UEs) in wireless communication systems. Power amplifiers typically amplify input signals of high frequencies into an output signal ready for radio transmission. High efficiency and linearity are generally desirable for power amplifiers to reduce power consumption and minimize errors and/or distortions in the output signal.

A power amplifier (PA) is one of the most power consuming components in a user equipment or base station. To reduce the power consumption as well as heat dissipation, higher efficiency is desirable for the PA. However, there is a trade-off between efficiency and linearity. As a result, when enhancing the efficiency of a PA, the PA may become more nonlinear and produce more distortion. To meet spurious emissions limits, these distortions, or errors, must be eliminated or corrected to a very low level.

Currently, pre-distortion and feedforward error correction are two of the most popular ways to linearize the PA. Pre-distortion, which can be done in the analog or digital domain, calculates the inverse model of the PA and pre-distorts the input signal provided to the PA. Ideally, if the PA inverse model is accurate, the PA output signal will be completely linearized. However, accurate modeling of the PA inverse model is very hard, especially for a PA with a high order of nonlinearity and deep memory effect. For example, in wideband applications, where the PA displays more memory effect, correction of errors using pre-distortion is more challenging. Furthermore, some of the error, such as noise, is not systematic but stochastic, which cannot be modeled, and cannot thus be corrected by the pre-distortion technique.

The complexity of feedforward error correction, unlike pre-distortion, is not impacted by the complexity of PA nonlinearity. Furthermore, feedforward error correction may correct both systematic errors, which can be modeled, and stochastic errors, which cannot be modeled. Its general structure is shown in FIG. 1, which shows an example of an amplifier circuit 100 (e.g. a power amplifier, PA) including a feedforward error correction circuit 102. When a signal is amplified by a PA 104, distortion (D) is produced, which is added to the desired PA 104 amplified signal (S). To eliminate or reduce the distortion, some of the signal output from the PA 104 is captured at a coupler 106 and subtract with the reference signal (R) at coupler 108. The reference signal is a duplication of (or may be proportional to) the signal to be amplified by the amplifier circuit 100, which can be captured by couplers 110 and 112 or generated, e.g. by a digital to analog converter (DAC) that is separate from a DAC that generates the signal provided to the PA 104. After the subtraction, only the distortion (D) or error remains and is provided to error amplifier (EPA) 114. This error signal is amplified to the appropriate amplitude by EPA 114 and is subtracted from the output signal of the PA 104 at coupler 116. As such, only the desired signal (S) is left at the output 118 of the amplifier circuit 100. In the example shown in FIG. 1, couplers 106 and 116 are usually directional couplers with low loss, whereas couplers 108, 110 and 112 can be directional couplers, or combiners/dividers. It is also worth noting that the feedforward structure can be used together with pre-distortion to eliminate the errors that cannot be corrected by pre-distortion.

Despite the aforementioned benefits, there is a drawback of feedforward error correction with respect to system efficiency. The coupler 116, being a directional coupler, has some unavoidable insertion loss (IL). The relation between IL and coupling is shown in equation 1 below. If the coupling factor is reduced, IL can be improved, but as a consequence, more power is needed from EPA 114. Since EPA 114 should be a linear amplifier to avoid distortion of the amplified error signal, its efficiency is always low. Therefore, the higher power capacity of the EPA 114, the more power it consumes. This power consumption of the EPA 114 lowers the efficiency of the whole circuit 100, especially for PAs with poor linearity, which means an error signal of higher power needs to be amplified by the EPA 114.

$$Insertionloss ( dB ) = 10 log ( 1 - {10}^{\frac{- Coupling}{10}} ) \qquad ( 1 )$$

WO 2017/082776A1, “An amplifier circuit for compensating an output signal from a circuit,” proposes a structure to eliminate the injection coupler 116, as shown in FIG. 2, which is a schematic block diagram illustrating an amplifier circuit. In the circuit shown in FIG. 2, the injection coupler is replaced by a network composed by several discrete error amplifiers (EPAs) 221, 222, 223 and 224. By assignment of proper magnitude of each EPA, as well as electric length of transmission lines 230 and 250 between each pair of EPAs, the reverse power seen by the main PA 210 from the EPA network can resemble a special function, such as maximal flatness or Chebyshev like function. The aim of the circuit of FIG. 2 is to suppress the reverse power over a wide frequency range while mitigating the power consumption of the EPA 114 in circuits such as the amplifier circuit 100 shown in FIG. 1.

In an example of the circuit shown in FIG. 2, there may be three EPAs (e.g. EPA 224 may not be present). Each transmission lines between each pair of EPAs 221, 222, 223 has electric length θ, which equals π/2, at center frequency f_{c}. Then, the reverse power at the combination point between main PA and first EPA can be expressed as:

$$T = {T}_{1} + {e}^{- 2 j θ} {T}_{2} + {e}^{- 4 j θ} {T}_{3} \qquad ( 2 )$$

Here T₁, T₂, T₃ denote the output power of the first, the second, and the third EPA. By choosing proper EPA powers to let T₁=T₃=½T₂, the expression forms 2-order binomial function, which equals 0 at f_{c}, and can achieve high directivity over wide frequency range. The number of EPAs can be changed to form other kinds of functions with arbitrary order.

### SUMMARY

One aspect of the present disclosure provides an amplifier error correction circuit. The circuit comprises a plurality of sub-amplifiers, a first input adapted to receive an output signal of an amplifier circuit, and an error signal input adapted to receive an error signal indicative of an error in the output signal of the amplifier circuit. The amplifier error correction circuit also comprises a sub-amplifier input signal preparation circuit adapted to provide a respective portion of the error signal to each of the sub-amplifiers, and an output signal combining circuit adapted to combine outputs of the sub-amplifiers with the output signal of the amplifier circuit and to provide a combined signal to an output of the amplifier correction circuit. At least one of the sub-amplifiers comprises a cascode amplifier.

Another aspect of the present disclosure provides an electronic device comprising an amplifier error correction circuit according to the above aspect.

### BRIEF DESCRIPTION OF THE DRAWINGS

For a better understanding of examples of the present disclosure, and to show more clearly how the examples may be carried into effect, reference will now be made, by way of example only, to the following drawings in which:

FIG. 1 shows an example of an amplifier circuit;

FIG. 2 is a schematic block diagram illustrating an amplifier circuit;

FIG. 3 illustrates an example of output impedance of an error signal amplifier;

FIG. 4 shows an example of an amplifier circuit including an amplifier error correction circuit;

FIG. 5 shows another example of an amplifier circuit including an amplifier error correction circuit;

FIG. 6 shows another example of an amplifier circuit including an amplifier error correction circuit;

FIG. 7 shows another example of an amplifier circuit including an amplifier error correction circuit;

FIG. 8 shows another example of an amplifier circuit including an amplifier error correction circuit;

FIG. 9 shows another example of an amplifier circuit including an amplifier error correction circuit;

FIG. 10 shows another example of an amplifier circuit including an amplifier error correction circuit;

FIG. 11 shows another example of an amplifier circuit including an amplifier error correction circuit;

FIG. 12 shows various examples of bias points for EPAs;

FIG. 13 shows the performance and output impedance of the EPAs;

FIG. 14 shows a simulated circuit of an error correction circuit;

FIG. 15 shows the directivity and insertion loss of the PA backend of the simulated circuit of FIG. 14;

FIG. 16 shows the power sweep and output impedance of a simulated cascode structure amplifier;

FIG. 17 shows a simulated error correction network;

FIG. 18 shows the directivity and insertion loss of the PA backend of the simulated circuit of FIG. 17; and

FIG. 19 is a graph illustrating the efficiency of various feedforward circuits described herein.

### DETAILED DESCRIPTION

The following sets forth specific details, such as particular embodiments or examples for purposes of explanation and not limitation. It will be appreciated by one skilled in the art that other examples may be employed apart from these specific details. In some instances, detailed descriptions of well-known methods, nodes, interfaces, circuits, and devices are omitted so as not obscure the description with unnecessary detail. Those skilled in the art will appreciate that the functions described may be implemented in one or more nodes using hardware circuitry (e.g., analog and/or discrete logic gates interconnected to perform a specialized function, ASICs, PLAs, etc.) and/or using software programs and data in conjunction with one or more digital microprocessors or general purpose computers. Nodes that communicate using the air interface also have suitable radio communications circuitry. Moreover, where appropriate the technology can additionally be considered to be embodied entirely within any form of computer-readable memory, such as solid-state memory, magnetic disk, or optical disk containing an appropriate set of computer instructions that would cause a processor to carry out the techniques described herein.

Hardware implementation may include or encompass, without limitation, digital signal processor (DSP) hardware, a reduced instruction set processor, hardware (e.g., digital or analogue) circuitry including but not limited to application specific integrated circuit(s) (ASIC) and/or field programmable gate array(s) (FPGA(s)), and (where appropriate) state machines capable of performing such functions.

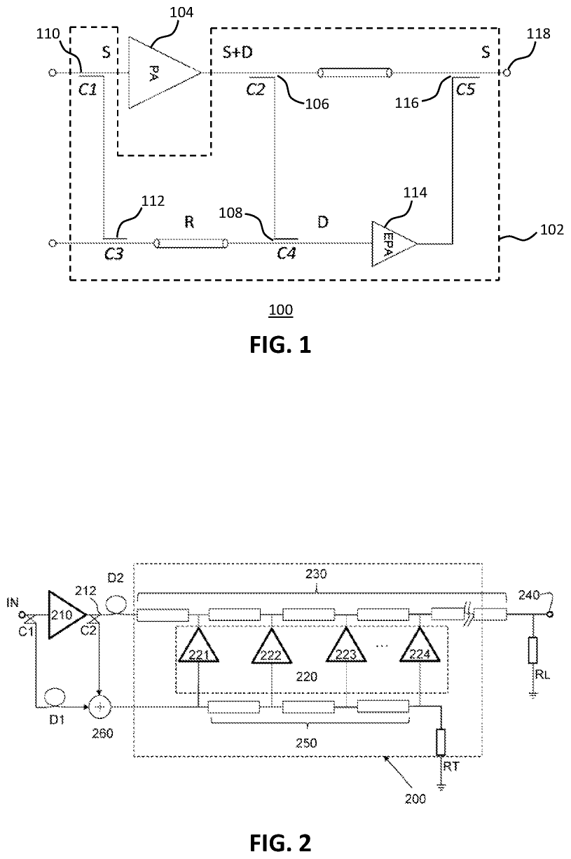

The main difference between the two types of feedforward error correction solutions discussed above is the way of error signal injection. In FIG. 1, for example, where a directional coupler is used (e.g. coupler 116), the loss on the backend of the main PA 104 can be reduced by the reduction of coupling factor, but the required power from the EPA 114, as well as EPA power consumption, increases. Therefore, reducing the coupling may have an impact on system efficiency.

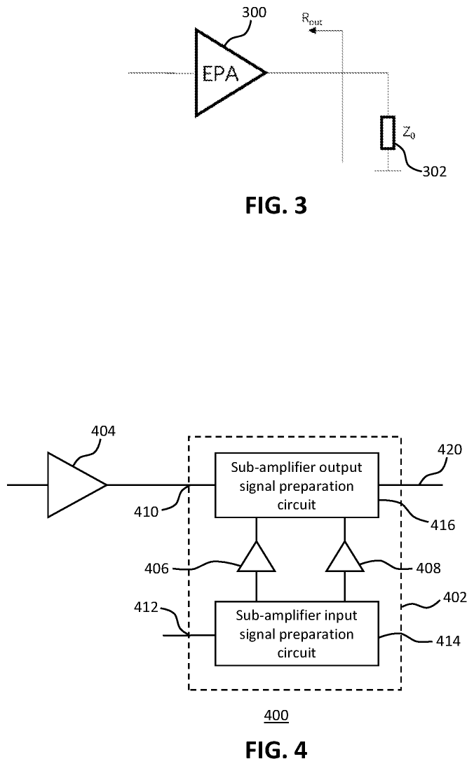

The technique discussed above with reference to FIG. 2 connects EPAs 221-224 directly to the backend of the main PA 210, thus minimizing the power loss of the EPAs. However, this can have big impact on the main PA, as illustrated in FIG. 3, which illustrates an example of output impedance of an error signal amplifier (EPA). Consider one EPA 300 with a matching network that is connected to a load 302 with impedance Z₀, and the EPA 300 output impedance seem from the load is Rₒᵤₜ. The EPA 300 itself could be a bipolar junction transistor (BJT), field effect transistor (FET), or any other kind of amplifier. For practical applications, it is usually in common-source or common-emitter configuration. Its output impedance (r_{ds} for FET and r_{ce} for BJT) is finite, which reduces with increased bias condition, such as class A, which is the typical working condition of an EPA due to the requirement of high linearity. Therefore, the magnitude of Rₒᵤₜ depends on the transistor itself, as well as the matching design. If it is a conjugate match, Rₒᵤₜ=Z₀. When connecting such an EPA 300 to the PA backend (e.g. PA 210 shown in FIG. 2) with characteristic impedance Z₀, it causes up to 3 dB power loss at the PA backend. For other designs, like maximal output power matching, Rₒᵤₜ can differ from Z₀, but is still finite, and loss in PA backend is unavoidable.

Examples of this disclosure provide amplifier error correction circuits that may provide for example an improved feedforward error correction, that may overcome the drawbacks of the two solutions discussed above with reference to FIGS. 1 and 2.

FIG. 4 shows an example of an amplifier circuit 400 including an amplifier error correction circuit 402 according to examples of this disclosure. The amplifier circuit 400 includes an amplifier 404 that provides an output signal to be corrected. For example, the amplifier 404 may be the main power amplifier (PA) in the amplifier circuit 400. The amplifier error correction circuit 402 includes a plurality of sub-amplifiers 406 and 408. There are two sub-amplifiers shown in the example of FIG. 4, though other examples may include more sub-amplifiers. A first input 410 of the amplifier error correction circuit 402 is adapted to receive an output signal of the amplifier 404 (which may be for example an amplifier circuit). An error signal input 412 of the amplifier error correction circuit 402 is adapted to receive an error signal indicative of an error in the output signal of the amplifier circuit. The error signal may be for example a signal that is proportional to an error in the output of the amplifier circuit 404. In some examples, the error signal may be determined in a similar manner to the error signal in FIGS. 1 and 2. For example, the error signal provided to the error signal input 412 may be similar to the signal provided to EPA 114 in FIG. 1, and hence could be determined for example using couplers 106 and 110 to extract a portion of the output and input signals of the amplifier circuit 404 respectively, and couplers 108 and 112 (and transmission line) to combine these extracted signals to obtain the error signal. Alternatively, for example, the error signal may be determined using any of the example techniques or components described below.

The amplifier error correction circuit 402 a sub-amplifier input signal preparation circuit 414 adapted to provide a respective portion of the error signal to each of the sub-amplifiers, and an output signal combining circuit 416 adapted to combine outputs of the sub-amplifiers with the output signal of the amplifier circuit and to provide a combined signal to an output 420 of the amplifier correction circuit. Thus, for example, each sub-amplifier 406, 408 may amplify its respective portion of the error signal provided to error signal input 412.

In some examples, at least one of the sub-amplifiers comprises a cascode amplifier. The cascode amplifier may comprise for example an amplifier (e.g. a BJT or FET) and a transistor (e.g. a BJT or FET) in a cascode arrangement. For example, the sub-amplifier may be connected at its output to a transistor in a common base or common gate configuration, where its base or gate is connected to a common voltage such as ground. In some examples, the cascode amplifier includes two transistors, where both transistors may be BJTs or FETs, though in other examples one transistor may be a BJT or FET whereas the other transistor may be the other of a BJT or FET.

Since in some examples the output impedance of the cascode amplifier is much higher than that of the sub-amplifiers shown in FIGS. 1 and 2, it ‘isolates’ the sub-amplifier from the power amplifier (PA) 404 backend. Thus, any loss at the PA backend caused by the insertion of the sub-amplifiers may be significantly reduced. On the other hand, the directivity over wideband of the sub-amplifier network may be almost unaffected. Thus, the cascode amplifier may significantly improve error correction system efficiency.

In some examples, the error correction circuit 402 may include an error detection circuit configured to derive the error signal from the output signal of the amplifier circuit and a reference input signal and to provide the error signal to the error signal input. For example, the error signal may be derived or determined in a similar manner as shown in FIG. 1 or 2 or according to any of the example embodiments described below. Alternatively, for example, the error correction circuit 402 may include an error signal generating circuit (e.g. a DAC) adapted to generate the error signal based on an input signal to the amplifier circuit 404 and a model of the amplifier circuit. The input signal to the amplifier circuit 404 may in such examples also include a further DAC to generate the input signal to the amplifier circuit 404.

In some examples, the sub-amplifier input signal preparation circuit 414 comprises an input transmission line, wherein inputs of at least two of the sub-amplifiers are coupled to different places along the input transmission line. The distance between the different places along the input transmission line may in some examples be a quarter wavelength at a center frequency of an operating frequency band of the circuit. Additionally or alternatively, in some examples, the distance between the different places along the input transmission line causes a phase delay of substantially 90 degrees at the center frequency of the operating frequency band of the circuit.

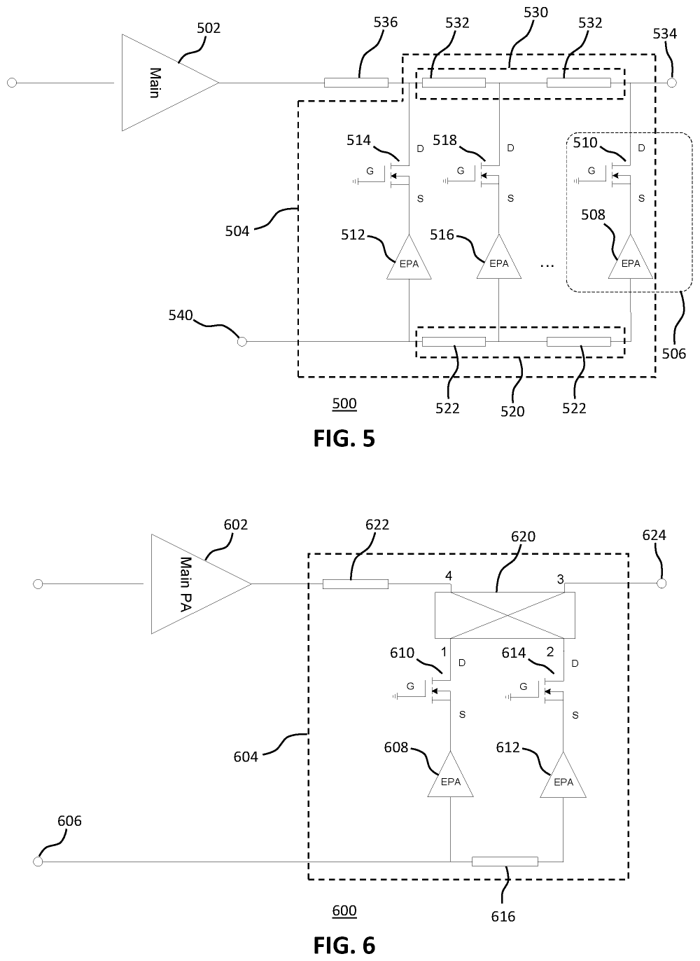

An example of such an arrangement is shown in FIG. 5, which shows an example of an amplifier circuit 500. The amplifier circuit 500 includes an amplifier 502 and an amplifier error correction circuit 504, which may be an example implementation of the amplifier error correction circuit 402 shown in FIG. 4. The amplifier error correction circuit 504 includes a plurality of sub-amplifiers (three sub-amplifiers are shown in this example). Each sub-amplifier is a cascode amplifier. For example, sub-amplifier 506 includes an amplifier 508 followed by a common-gate connected FET 510. Similarly, another sub-amplifier comprises amplifier 512 followed by common-gate connected FET 514, and a further sub-amplifier comprises amplifier 516 followed by common-gate connected FET 518.

The amplifier error correction circuit 504 includes an input signal preparation circuit 520 that includes input transmission line, represented in FIG. 5 by portions 522 of a transmission line. The inputs of the sub-amplifiers in the amplifier error correction circuit 504 are thus coupled to different places along the input transmission line, and the distance between the different places along the input transmission line 522 may in some examples is a quarter wavelength at a center frequency of an operating frequency band of the circuit 500. Additionally or alternatively, the distance between the different places along the input transmission line causes a phase delay of substantially 90 degrees at the center frequency of the operating frequency band of the circuit 500.

In some examples, the output signal combining circuit 416 shown in FIG. 4 comprises an output transmission line coupled between the first input 410 and the output 420 of the amplifier error correction circuit 402, wherein outputs of at least two of the sub-amplifiers are coupled to different places along the output transmission line. This is also shown in the example of FIG. 5, where the amplifier error correction circuit 504 includes an output signal combining circuit 530 that includes an output transmission line, represented in FIG. 5 by portions 532 of a transmission line. The output transmission line is coupled between the first input (which receives the output of the amplifier 502) and the output 534 of the amplifier error correction circuit 504. In the example shown in FIG. 5, an additional portion of a transmission line 536 is located between the output of the amplifier 502 and the output signal combining circuit 530. An error signal input 540 is adapted to receive the error signal.

In some examples, the distance between the different places along the output transmission line is a quarter wavelength at the center frequency of an operating frequency band of the circuit. Additionally or alternatively, in some examples, the distance between the different places along the output transmission line causes a phase delay of substantially 90 degrees at the center frequency of the operating frequency band of the circuit.

The segments or portions of the output transmission line (e.g. those portions 532 shown in FIG. 5) between the outputs of the sub-amplifiers may in some examples have a same characteristic impedance, and supply voltages for the sub-amplifiers are increased along the output transmission line towards the output port 534. Alternatively, in some examples, supply voltages for the sub-amplifiers may be equal, and the characteristic impedance of segments or portions (e.g. portions 532 shown in FIG. 5) of the output transmission line between the outputs of the sub-amplifiers decreases along the output transmission line towards the output port 534.

In some examples, in the amplifier circuits as disclosed herein, output currents of the sub-amplifiers along the output transmission line are weighted according to a window function. For example, the window function is bell-shaped and/or is any one of Dolph-Chebyshev, Gaussian, Binomial, Flamming or Blackman, or a combination thereof.

FIG. 6 shows another example of an amplifier circuit 600. The circuit 600 includes an amplifier 602 and an amplifier error correction circuit 604. An error signal input 606 is adapted to receive the error signal. The amplifier error correction circuit 604 includes a first sub-amplifier consisting of amplifier 608 followed by common-gate connected FET 610, and a second sub-amplifier consisting of amplifier 612 followed by common-gate connected FET 614. In the example shown in FIG. 6, input signal preparation circuit comprises an input transmission line 616 connected between the inputs of the sub-amplifiers.

Also in the example shown in FIG. 6, the output signal combining circuit comprises an output signal hybrid coupler 620. An input port (labelled as port 4 in FIG. 6) of the output signal hybrid coupler 620 is coupled to the first input (via a transmission line 622 in the example shown in FIG. 6), which receives the output of the amplifier 602. A transmitted port (labelled as port 1 in FIG. 6) of the output signal hybrid coupler 620 is coupled to an output of a first sub-amplifier of the plurality of sub-amplifiers (in this case, the drain of transistor 610). A coupled port (labelled as port 2 in FIG. 6) of the output signal hybrid coupler 620 is coupled to an output of a second sub-amplifier of the plurality of sub-amplifiers (in this case, the drain of transistor 614). Finally, an isolated port (labelled as port 3 in FIG. 6) of the output signal hybrid coupler 620 is coupled to the output 624 of the amplifier error correction circuit.

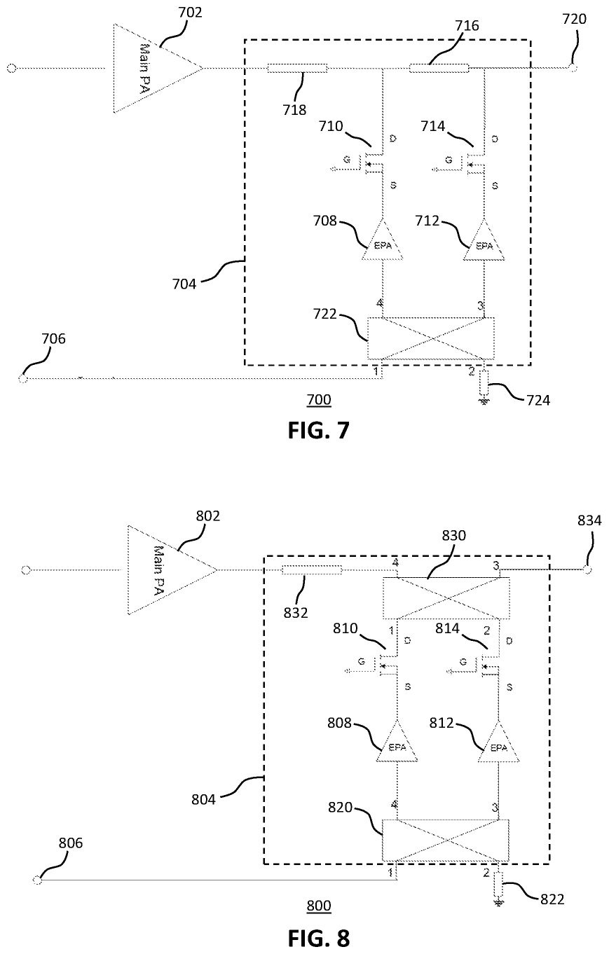

FIG. 7 shows another example of an amplifier circuit 700. The circuit 700 includes an amplifier 702 and an amplifier error correction circuit 704. An error signal input 706 is adapted to receive the error signal. The amplifier error correction circuit 704 includes a first sub-amplifier consisting of amplifier 708 followed by common-gate connected FET 710, and a second sub-amplifier consisting of amplifier 712 followed by common-gate connected FET 714. In the example shown in FIG. 7, output signal preparation circuit comprises an output transmission line 716 connected between the first input (via a transmission line 718 in the example shown in FIG. 7), which receives the output of the amplifier 702, and output 720.

In the example shown in FIG. 7, the sub-amplifier input signal preparation circuit comprises an sub-amplifier input hybrid coupler 722. An input port (labelled as port 1 in FIG. 7) of the sub-amplifier input hybrid coupler 722 is adapted to receive the error signal (e.g. is coupled to error signal input 706). A transmitted port (labelled as port 4 in FIG. 7) of the sub-amplifier input hybrid coupler 722 is coupled to an input of a first sub-amplifier of the plurality of sub-amplifiers (in this case, the input of amplifier 708). A coupled port (labelled as port 3 in FIG. 7) of the sub-amplifier input hybrid coupler 722 is coupled to an input of a second sub-amplifier of the plurality of sub-amplifiers (in this case, the input of amplifier 712). Finally, an isolated port (labelled as port 2 in FIG. 7) of the sub-amplifier input hybrid coupler 722 is coupled to a load 724.

Thus, in view of the above, either the input signal preparation circuit or the output signal combining circuit could be a hybrid coupler. In some examples, both the input signal preparation circuit and the output signal combining circuit could each comprise a hybrid coupler. Such an arrangement is shown in FIG. 8, which shows another example of an amplifier circuit 800. The circuit 800 includes an amplifier 802 and an amplifier error correction circuit 804. An error signal input 806 is adapted to receive the error signal. The amplifier error correction circuit 804 includes a first sub-amplifier consisting of amplifier 808 followed by common-gate connected FET 810, and a second sub-amplifier consisting of amplifier 812 followed by common-gate connected FET 814.

In the example shown in FIG. 8, the sub-amplifier input signal preparation circuit comprises a sub-amplifier input hybrid coupler 820. An input port (labelled as port 1 in FIG. 8) of the sub-amplifier input hybrid coupler 820 is adapted to receive the error signal (e.g. is coupled to error signal input 806). A transmitted port (labelled as port 4 in FIG. 8) of the sub-amplifier input hybrid coupler 820 is coupled to an input of a first sub-amplifier of the plurality of sub-amplifiers (in this case, the input of amplifier 808). A coupled port (labelled as port 3 in FIG. 8) of the sub-amplifier input hybrid coupler 820 is coupled to an input of a second sub-amplifier of the plurality of sub-amplifiers (in this case, the input of amplifier 812). Finally, an isolated port (labelled as port 2 in FIG. 8) of the sub-amplifier input hybrid coupler 820 is coupled to a load 822.

Also as shown in FIG. 8, the output signal combining circuit comprises an output signal hybrid coupler 830. An input port (labelled as port 4 in FIG. 8) of the output signal hybrid coupler 830 is coupled to the first input (via a transmission line 832 in the example shown in FIG. 8), which receives the output of the amplifier 802. A transmitted port (labelled as port 1 in FIG. 8) of the output signal hybrid coupler 830 is coupled to an output of a first sub-amplifier of the plurality of sub-amplifiers (in this case, the drain of transistor 810). A coupled port (labelled as port 2 in FIG. 8) of the output signal hybrid coupler 830 is coupled to an output of a second sub-amplifier of the plurality of sub-amplifiers (in this case, the drain of transistor 814). Finally, an isolated port (labelled as port 3 in FIG. 8) of the output signal hybrid coupler 830 is coupled to the output 834 of the amplifier error correction circuit 804.

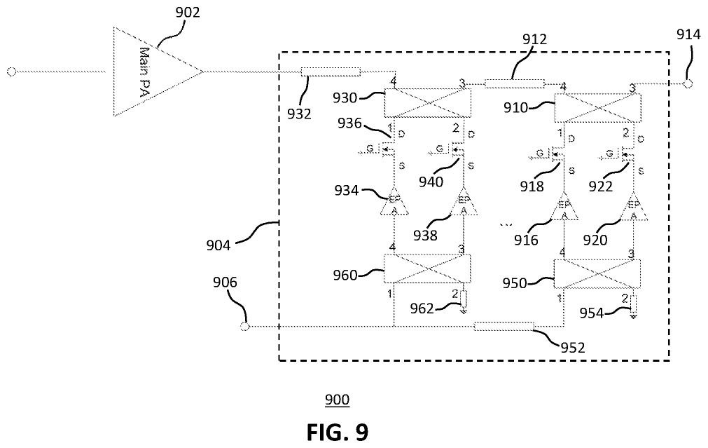

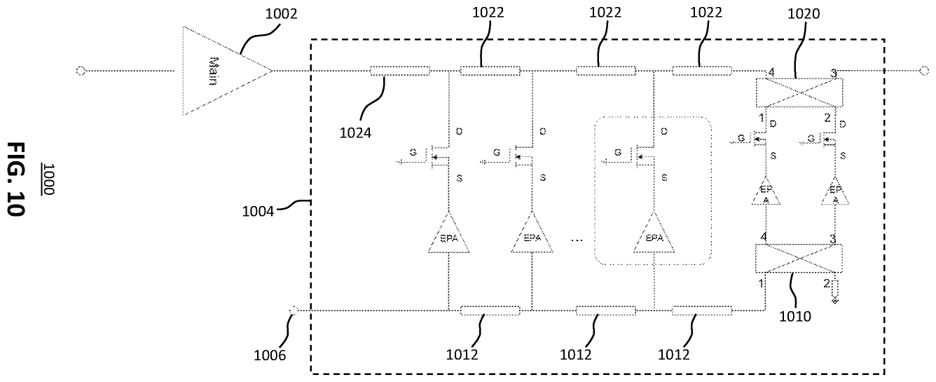

In some examples, the input signal preparation circuit and/or the output signal combining circuit may include multiple hybrid couplers. An example of this arrangement, where both the input signal preparation circuit and the output signal combining circuit each include a pair of hybrid couplers, is shown in FIG. 9, which shows another example of an amplifier circuit 900. The circuit 900 includes an amplifier 902 and an amplifier error correction circuit 904. An error signal input 906 is adapted to receive the error signal.

In FIG. 9, the output signal combining circuit comprises a first output signal hybrid coupler 910. An input port (labelled as port 4 in FIG. 9) of the first output signal hybrid coupler 910 is coupled to an output transmission line 912 such that the first output signal hybrid coupler 910 is coupled between the output transmission line 912 and the output 914 of the amplifier error correction circuit. A transmitted port (labelled as port 1 in FIG. 9) of the first output signal hybrid coupler 910 is coupled to an output of a first sub-amplifier of the plurality of sub-amplifiers. In this example, the first sub-amplifier comprises amplifier 916 and common-gate connected FET 918, such that the drain of FET 918 is provided to the transmitted port of the first output signal hybrid coupler 910. A coupled port (labelled as port 2 in FIG. 9) of the first output signal hybrid coupler 910 is coupled to an output of a second sub-amplifier of the plurality of sub-amplifiers. In this example, the second sub-amplifier comprises amplifier 920 and common-gate connected FET 922, such that the drain of FET 922 is provided to the coupled port of the first output signal hybrid coupler 910. An isolated port (labelled as port 3 in FIG. 9) of the first output signal hybrid coupler 910 is coupled to the output 914 of the amplifier error correction circuit 904.

In addition, the output signal combining circuit comprises a second output signal hybrid coupler 930. An input port (labelled as port 4 in FIG. 9) of the second output signal hybrid coupler 930 is coupled to the first input, which receives the output of the amplifier 902 (in the example shown, via transmission line or delay line 932). A transmitted port (labelled as port 1 in FIG. 9) of the second output signal hybrid coupler 930 is coupled to an output of a third sub-amplifier of the plurality of sub-amplifiers. In this example, the third sub-amplifier comprises amplifier 934 and common-gate connected FET 936, such that the drain of FET 936 is provided to the transmitted port of the second output signal hybrid coupler 930. A coupled port (labelled as port 2 in FIG. 9) of the second output signal hybrid coupler 930 is coupled to an output of a fourth sub-amplifier of the plurality of sub-amplifiers. In this example, the fourth sub-amplifier comprises amplifier 938 and common-gate connected FET 940, such that the drain of FET 940 is provided to the coupled port of the second output signal hybrid coupler 930. An isolated port (labelled as port 3 in FIG. 9) of the second output signal hybrid coupler 930 is coupled to the output transmission line 912 such that the second output signal hybrid coupler 930 is coupled between the first input and the output transmission line 912.

Also in the example shown in FIG. 9, the sub-amplifier input signal preparation circuit comprises a first sub-amplifier input hybrid coupler 950. An input port (labelled as port 1 in FIG. 9) of the first sub-amplifier input hybrid coupler 950 is coupled to an end of an input transmission line 952. A transmitted port (labelled as port 4 in FIG. 9) of the first sub-amplifier input hybrid coupler 950 is coupled to an input of the first sub-amplifier (i.e. the input of amplifier 916). A coupled port (labelled as port 3 in FIG. 9) of the first sub-amplifier input hybrid coupler 950 is coupled to an input of the second sub-amplifier (i.e. the input of amplifier 920). An isolated port (labelled as port 2 in FIG. 9) of the first sub-amplifier input hybrid coupler 950 is coupled to a load 954.

The sub-amplifier input signal preparation circuit also comprises a second sub-amplifier input hybrid coupler 960. An input port (labelled as port 1 in FIG. 9) of the second sub-amplifier input hybrid coupler 960 is adapted to receive the error signal (i.e. is connected to error signal input 906). A transmitted port (labelled as port 4 in FIG. 9) of the second sub-amplifier input hybrid coupler 960 is coupled to an input of the third sub-amplifier (i.e. the input of amplifier 934). A coupled port (labelled as port 3 in FIG. 9) of the second sub-amplifier input hybrid coupler 960 is coupled to an input of the fourth sub-amplifier (i.e. the input of amplifier 938). An isolated port (labelled as port 2 in FIG. 9) of the second sub-amplifier input hybrid coupler 960 is coupled to a load 962.

FIG. 10 shows another example of an amplifier circuit 1000. The circuit 1000 includes an amplifier 1002 and an amplifier error correction circuit 1004. An error signal input 1006 is adapted to receive the error signal.

The input signal preparation circuit of the amplifier error correction circuit 1004 includes a hybrid coupler 1010 connected to two sub-amplifiers in a manner similar to the first hybrid coupler 950 shown in FIG. 9. However, in the example shown in FIG. 10, the transmission line 952 is represented by segments or portions 1012 of an input signal transmission line, and inputs of multiple sub-amplifiers (three in this example) are connected to different places along the input signal transmission line, for example in a manner similar to that described above with reference to FIG. 5 and the portions 522 of the input signal transmission line.

Similarly, the output signal preparation circuit of the amplifier error correction circuit 1004 includes a hybrid coupler 1020 connected to two sub-amplifiers in a manner similar to the first hybrid coupler 910 shown in FIG. 9. However, in the example shown in FIG. 10, segments or portions 1022 of an output signal transmission line are connected between the first input (that receives the output of the amplifier 1002, in this example via transmission or delay line 1024), and inputs of multiple sub-amplifiers (three in this example) are connected to different places along the output signal transmission line, for example in a manner similar to that described above with reference to FIG. 5 and the portions 532 of the output signal transmission line.

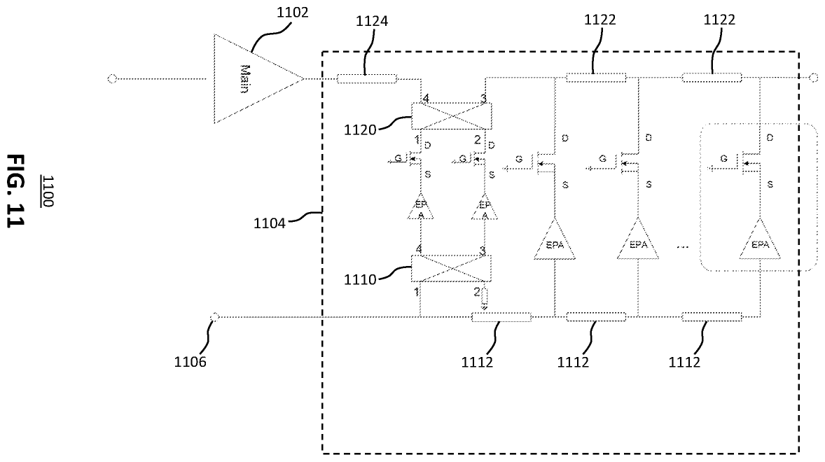

FIG. 11 shows another example of an amplifier circuit 1100. The circuit 1100 includes an amplifier 1102 and an amplifier error correction circuit 1104. An error signal input 1106 is adapted to receive the error signal.

The input signal preparation circuit of the amplifier error correction circuit 1104 includes a hybrid coupler 1110 connected to two sub-amplifiers in a manner similar to the second hybrid coupler 960 shown in FIG. 9. However, in the example shown in FIG. 11, the transmission line 952 is represented by segments or portions 1112 of an input signal transmission line, and inputs of multiple sub-amplifiers (three in this example) are connected to different places along the input signal transmission line, for example in a manner similar to that described above with reference to FIG. 5 and the portions 522 of the input signal transmission line.

Similarly, the output signal preparation circuit of the amplifier error correction circuit 1104 includes a hybrid coupler 1120 connected to two sub-amplifiers in a manner similar to the second hybrid coupler 930 shown in FIG. 9. However, in the example shown in FIG. 11, segments or portions 1122 of an output signal transmission line are connected between the first input (that receives the output of the amplifier 1102, in this example via transmission or delay line 1124), and inputs of multiple sub-amplifiers (three in this example) are connected to different places along the output signal transmission line, for example in a manner similar to that described above with reference to FIG. 5 and the portions 532 of the output signal transmission line.

In general, an amplifier error correction circuit according to this disclosure may include any of the examples of an input signal preparation circuit in any of the examples described above and shown in FIGS. 5-11, where appropriate. These are example implementations of ways to provide input signals to the sub-amplifiers based on the error signal, and any suitable means for achieving this may be used. Also, an amplifier error correction circuit according to this disclosure may include any of the examples of an output signal preparation circuit in any of the examples described above and shown in FIGS. 5-11, where appropriate. These are example implementations of ways to combine the output of the main amplifier with the outputs of the sub-amplifiers, and any suitable means for achieving this may be used. In addition, the sub-amplifier error correction circuit may include any number of two or more sub-amplifiers where appropriate.

Results of a simulation of an example amplifier circuit including an example amplifier error correction circuit will now be described. The simulated circuit is the circuit 500 shown in FIG. 5. A FET is used for each sub-amplifier. Statz model is used to model the EPA as shown below in equation 2. For cascode amplifiers, we use the same FET device in common gate structure for output stage transistor.

$${I}_{ds} = \{ \begin{matrix}\frac{{β ( {V}_{gs} - {V}_{T} )}^{2}}{1 + B ( {V}_{gs} - {V}_{T} )} ( 1 + λ {V}_{ds} ) [ 1 - {( 1 - \frac{α {V}_{ds}}{3} )}^{3} ] 0 < {V}_{ds} < \frac{3}{α} \\ \frac{{β ( {V}_{gs} - {V}_{T} )}^{2}}{1 + B ( {V}_{gs} - {V}_{T} )} ( 1 + λ {V}_{ds} ) {V}_{ds} \geq \frac{3}{α}\end{matrix} \qquad ( eq . 2 )$$

For simulation, we choose V_{T}=−4, β=0.02, λ=0.015, α=3.4, B=0.0569, and Iₘₐₓ=0.4 A. Three sub-amplifiers are used that form a 2^{nd} order Chebyshev-like structure as an example, and the targeted relative bandwidth is 40%. However, as note above, other examples may use other configurations that represent different functions. The expression of the 2^{nd} Chebyshev polynomial is as below in equation 3:

$${T}_{2} ( x ) = 2 {x}^{2} - 1 \qquad ( eq . 3 )$$

This has equal ripple within −1≤x≤1. At center frequency, the length of each transmission line equals quarter-wavelength, or the electric length

$${θ}_{c} = \frac{π}{2} .$$

At the lower side of the target frequency bandwidth, the electric length of the transmission line is assumed to be θₘ. Then we have:

$$2 \frac{{θ}_{c} - {θ}_{m}}{{θ}_{c}} = 40 \% , {θ}_{m} = 0.4 π \qquad ( eq . 4 )$$

By mapping θₘ to x=1 and π−θₘ to x=−1, or

$$x = \frac{cos θ}{cos {θ}_{m}} ,$$

we can have equal ripple within the desired frequency range, if the network forms Chebyshev like structure as:

$${T}_{2} ( \frac{cos θ}{cos {θ}_{m}} ) = A [ {sec}^{2} {θ}_{m} ( 1 + cos 2 θ ) - 1 ] \qquad ( eq . 5 )$$

For the three sub-amplifiers, at the combination point between the 1^{st} EPA and main PA, the reflection or reverse signal from EPAs can be written as:

$$T ( θ ) = {T}_{1} + {T}_{2} {e}^{- 2 j θ} + {T}_{3} {e}^{- 4 j θ} \qquad ( eq . 6 )$$

Where T₁, T₂, T₃ is the transmission from the 1^{st}, 2^{nd}, and 3^{rd} EPA. By equaling T(θ) with

$${T}_{2} ( \frac{cos θ}{cos {θ}_{m}} ) ,$$

we have T₁:T₂:T₃=1:1.81:1.

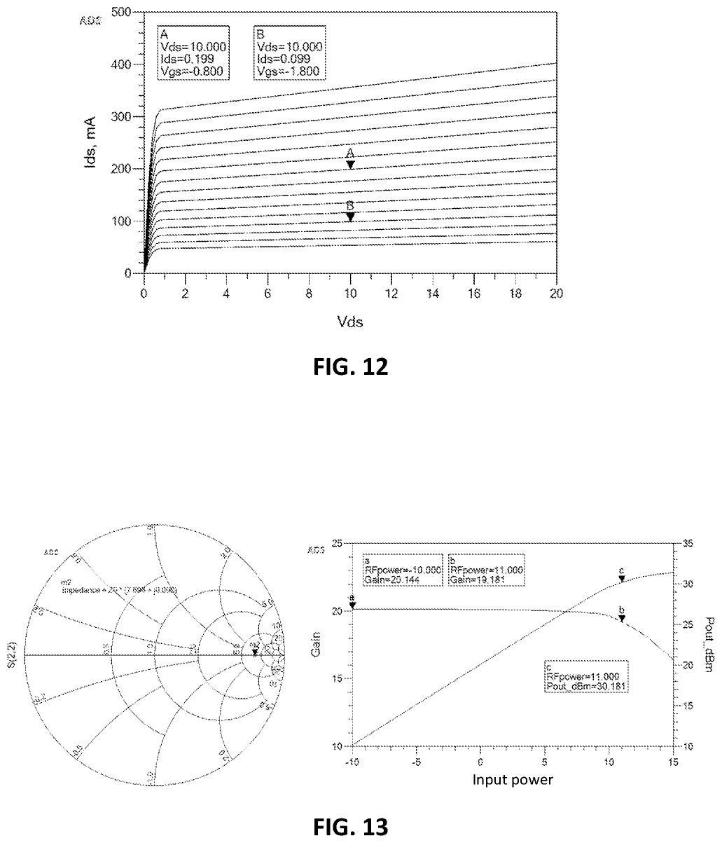

Simulation is performed for the above-mentioned simulated circuit, and also for the circuit shown in FIG. 2. First, the EPAs shown in FIG. 2 are considered. We set the bias point at point A in FIG. 12, which shows various examples of bias points for EPAs. At point A, V_{ds}=10V, V_{gs}=−0.8V, and I_{ds}=0.2 A. Since the EPAs need high linearity, we assume these operate in class A, thus the maximal output power roughly equals 0.5*V_{ds}*I_{ds}=1 W=30 dBm, and the desired load impedance is V_{ds}/I_{ds}=50 ohm. FIG. 13 shows the performance and output impedance of the EPAs. As expected, the maximal output power (or P1 dB) is about 30.2 dBm, close to the target 30 dBm. Its output impedance is about 385 ohm.

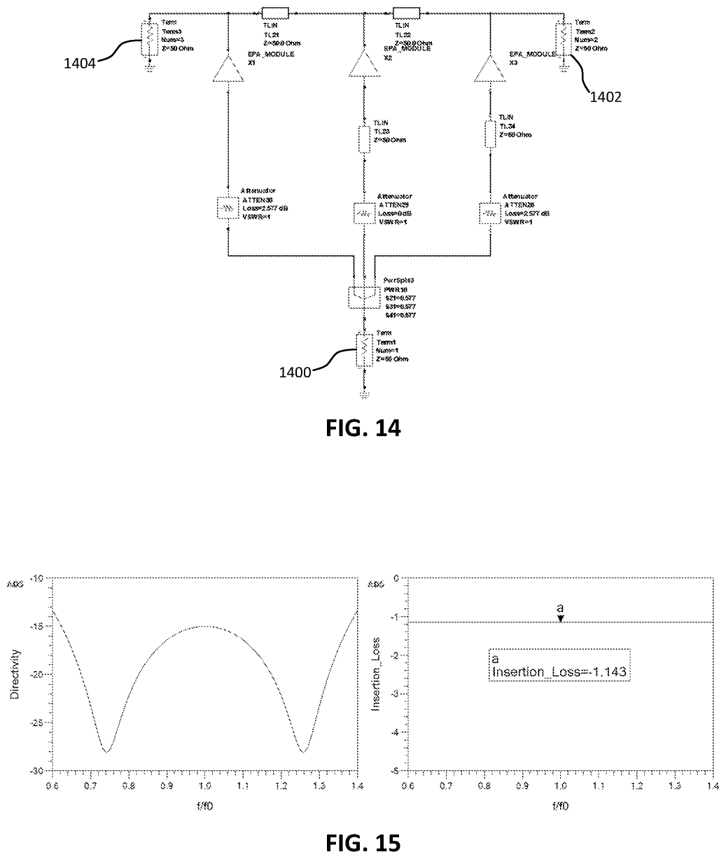

Next, the performance of the EPA network in of FIG. 2 is examined. The simulated circuit is shown FIG. 14, where the EPA in the middle can output 2.577 dB or 1.81 times higher power than other two EPAs, so the three EPAs form a 2^{nd} order Chebyshev-like structure. Terminal 3 represents the output port of the main PA, while terminal 2 represents the output port of the error correction circuit. The characteristic impedance of transmission line Z₀ is 50 ohm.

In FIG. 14, there are three terminals. Terminal 1 1400 represents error signal input 412 of FIG. 4. Terminal 2 1402 represents the output port 420 of the error correction circuit 402. Terminal 3 1404 represents the first input 410 of FIG. 4. Below, the parameter S21 refers to a signal input from term 1 1400, output from term 2 1402. This represents error signal forward transmission. Parameter S31 refers to signal input from term 1 1400, output from term 3 1404. This represents error signal reverse transmission. S21-S31 is the directivity. Most of the error signal is expected to go to term 2 1402, less signal that goes to term 3 1404. Parameter S23 refers to the transmission loss when a signal input from term 3 1404, output from term 2 1402. This represents the signal transmission loss for the circuit 400 of FIG. 4 for the main amplifier 404.

The directivity and insertion loss of the error correction circuit is shown in FIG. 15. Here we have Directivity=S21−S31 in dB, and Insertion loss=S23. We can see that this kind of structure achieves a high directivity over wide frequency range, but the price is high loss at main PA output, which can impact system efficiency a lot. This is caused by the finite ratio between the output impedance of EPA and Z₀.

A simulation of examples of this disclosure, including a cascode amplifier e.g. with one or more added common-gate FET, will now be described. The bias point of the added common-gate FET in each cascode amplifier is set at the point A in FIG. 12. The gain of this device is much lower than the other device (e.g. in common-source structure) in the cascode amplifier, since it has no current gain. However, its gain can still be positive, and this allows for a lower bias point for the input stage in common-source connected FET device, which can lower system power consumption. For example, point B in FIG. 12 may be chosen to be the bias point of the EPA in the cascode amplifier, where V_{ds}=10V, V_{gs}=−1.8V, and I_{ds}=0.1 A.

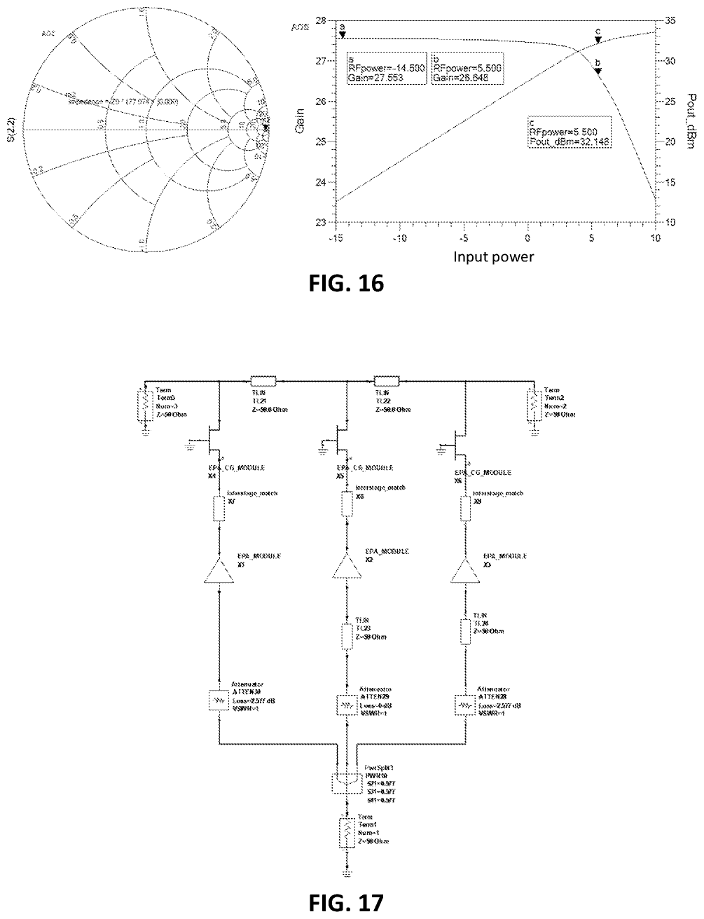

FIG. 16 shows the power sweep and output impedance of the cascode structure itself, where the common-gate stage FET is added after the common-source stage FET. The output impedance is extremely high (about 3.8 kohm), and its P1 dB is about 32.1 dBm, which is higher than the value of the single stage EPA in the simulation of the circuit of FIG. 2/FIG. 14. Therefore, the cascode structure should be able to inject at least the same power level of error signal, compared to the common-source EPA of FIG. 2/FIG. 14.

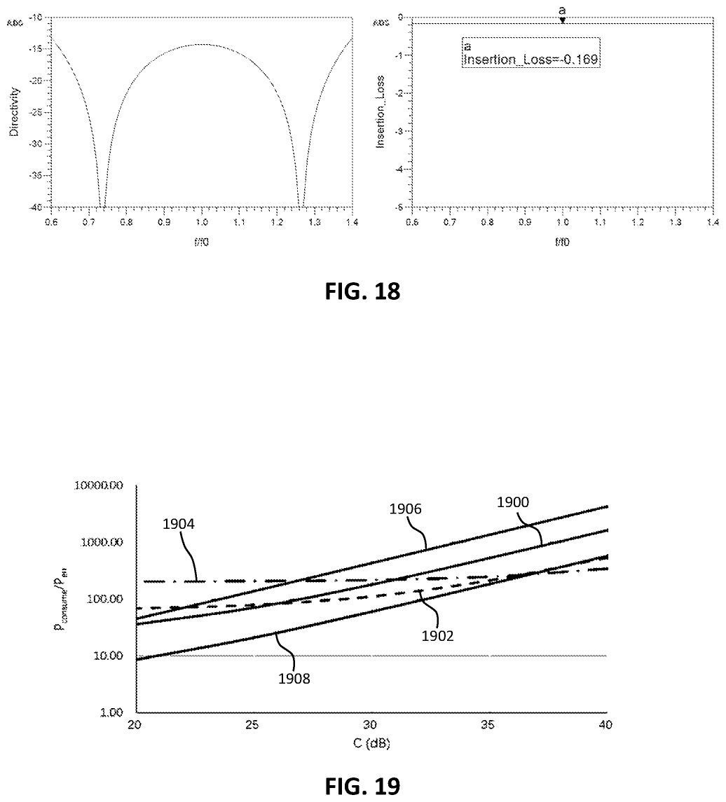

Next, the performance of a simulated sub-amplifier network according to this disclosure is examined. FIG. 17 shows the simulated circuit. The directivity and insertion loss of the error correction circuit is shown in FIG. 18. It is clear that the directivity is almost the same as That shown in FIG. 15. Meanwhile, due to the significantly increased output impedance of the cascode arrangements, the loss after main PA is greatly reduced. Thus, in the proposed structure, two advantages are achieved simultaneously: namely, to minimize the insertion loss at the PA backend, and to minimize the power consumption of the EPA.

Next, a simple comparison of system efficiency, or power consumption, between the three feedforward solutions is performed. The three solutions are the traditional solution with directional coupler (e.g. as shown in FIG. 1), a solution with an EPA network as shown in FIG. 2, and solutions according to this disclosure, such as those shown in FIGS. 4-11 and that described in the simulation described above.

We assume the power of wanted signal at the output of transmission system is P_{c}, and the peak power of error signal to be corrected is Pₑᵣᵣ, where we define C=P_{c}/Pₑᵣᵣ (dB) to be the ratio between these two. For the main PA, we assume the efficiency is η=0.7. We will compare the power consumption of each solution, with the same output power P_{c} and the same error power Pₑᵣᵣ that needs to be corrected.

To obtain high linearity, the EPA always woks in class A, where the efficiency at peak output power is 50%. For example, for EPA with 1 W peak output power, its power consumption is 1 W/50%=2 W. This value consists with the value that is used in the simulation for the solution with original EPA network (e.g. as in FIG. 2), where the EPA power consumption is about V_{ds}*I_{ds}=2 W, while the power output capacity is about 1 W. Here we use P1 dB to characterize the power capacity of EPA. So, if the peak power of error signal is Per, the EPA power consumption in the original EPA network is Pₑᵣᵣ/50%=2*Pₑᵣᵣ.

In the EPA networks proposed herein, i.e. including at least one cascode amplifier, EPA power consumption is higher, since one more device is added. In the simulation, the power consumption of the two devices is V_{ds1}*I_{ds1}+V_{ds2}*I_{ds2}=2.84 W, which is about 42% higher than the value in original EPA network. So, it is reasonable to assume that EPA power consumption in our proposed structure is about 2.84*Pₑᵣᵣ.

In the traditional structure (e.g. as in FIG. 1), a directional coupler with coupling CPL (dB) is used, so the power consumption of EPA is 10^{(CPL/10)}*2*Pₑᵣᵣ.

For the whole transmission system, the power consumption comes from two parts: the DC consumption of EPA link, and the power consumption due to loss at PA backend. The latter term can be calculated according to equation 7 below:

$${P}_{loss} = {P}_{c} * \frac{{10}^{\frac{- IL}{10}} - 1}{η} = {10}^{\frac{C}{10}} * \frac{{10}^{\frac{- IL}{10}} - 1}{η} * {P}_{err} \qquad ( eq . 7 )$$

Where IL is the PA backend insertion loss, and η=70% is main PA efficiency. For the traditional solution, IL is expressed in equation 1, while for the solution with original and improved EPA network, IL is −1.143 dB and −0.169 dB, respectively. Therefore, the total power consumption of the system is:

$${P}_{consume} = {P}_{loss} + {P}_{EPA} \qquad ( eq . 8 )$$

FIG. 19 is a graph illustrating the efficiency of various error correction circuits described herein. Curve 1900 in FIG. 19 represents efficiency of a circuit such as that shown in FIG. 1, where CPL=10 dB. Curve 1902 represents efficiency of a circuit such as that shown in FIG. 1, where CPL=15 dB. Curve 1904 represents efficiency of a circuit such as that shown in FIG. 1, where CPL=20 dB. Curve 1906 represents efficiency of the EPA network of FIG. 2. Curve 1908 represents efficiency of the EPA network including cascode amplifier(s) as disclosed herein, shown in FIG. 5 or 17 for example.

For each of the curves shown in FIG. 19, P_{consume}/Pₑᵣᵣ versus C is depicted, where we choose the range of C to be 20 dB˜40 dB, which is the typical ratio between signal power and error signal peak power in communication system. For curves 1900, 1902 and 1904, we choose CPL from 10 dB to 20 dB, which is also the most common used value in real applications. FIG. 19 reveals how much power consumption is required for each solution. It can be seen that, to correct the same power level of error, in most cases, curve 1908 shows that feedforward systems and EPA/sub-amplifier networks in accordance with this disclosure consume the least power. Only in systems with good linearity (e.g. C>35 dB), where the power of the wanted signal is much higher than the error signal power, solutions such as those shown in FIG. 1 with proper coupling value can consume less power. In systems with poor linearity (C<35 dB), where the linearization technique may be necessary, solutions according to this disclosure are always the most power efficient, and this benefit over other solutions increases with decreased C.

It should be noted that the above-mentioned examples illustrate rather than limit the invention, and that those skilled in the art will be able to design many alternative examples without departing from the scope of the appended statements. The word “comprising” does not exclude the presence of elements or steps other than those listed in a claim, “a” or “an” does not exclude a plurality, and a single processor or other unit may fulfil the functions of several units recited in the statements below. Where the terms, “first”, “second” etc. are used they are to be understood merely as labels for the convenient identification of a particular feature. In particular, they are not to be interpreted as describing the first or the second feature of a plurality of such features (i.e. the first or second of such features to occur in time or space) unless explicitly stated otherwise. Steps in the methods disclosed herein may be carried out in any order unless expressly otherwise stated. Any reference signs in the statements shall not be construed so as to limit their scope.

1. An amplifier error correction circuit comprising:
a plurality of sub-amplifiers;
a first input adapted to receive an output signal of an amplifier circuit;
an error signal input adapted to receive an error signal indicative of an error in the output signal of the amplifier circuit;
a sub-amplifier input signal preparation circuit adapted to provide a respective portion of the error signal to each of the sub-amplifiers; and
an output signal combining circuit adapted to combine outputs of the sub-amplifiers with the output signal of the amplifier circuit and to provide a combined signal to an output of the amplifier correction circuit;
wherein at least one of the sub-amplifiers comprises a cascode amplifier.

2. The amplifier error correction circuit of claim 1, comprising an error detection circuit configured to derive the error signal from the output signal of the amplifier circuit and a reference input signal and to provide the error signal to the error signal input.

3. The amplifier error correction circuit of claim 1, comprising an error signal generating circuit adapted to generate the error signal based on an input signal to the amplifier circuit and a model of the amplifier circuit.

4. The amplifier error correction circuit of claim 1, wherein the sub-amplifier input signal preparation circuit comprises an input transmission line, wherein inputs of at least two of the sub-amplifiers are coupled to different places along the input transmission line.

5. The amplifier error correction circuit of claim 4, wherein the distance between the different places along the input transmission line is a quarter wavelength at a center frequency of an operating frequency band of the circuit, and/or the distance between the different places along the input transmission line causes a phase delay of substantially 90 degrees at the center frequency of the operating frequency band of the circuit.

6. The amplifier error correction circuit of claim 4, wherein the sub-amplifier input signal preparation circuit comprises a first sub-amplifier input hybrid coupler, wherein an input port of the first sub-amplifier input hybrid coupler is coupled to an end of the input transmission line, a transmitted port of the first sub-amplifier input hybrid coupler is coupled to an input of a first sub-amplifier of the plurality of sub-amplifiers, a coupled port of the first sub-amplifier input hybrid coupler is coupled to an input of a second sub-amplifier of the plurality of sub-amplifiers, and an isolated port of the first sub-amplifier input hybrid coupler is coupled to a load.

7. The amplifier error correction circuit of claim 1, wherein the sub-amplifier input signal preparation circuit comprises a second sub-amplifier input hybrid coupler, wherein an input port of the second sub-amplifier input hybrid coupler is adapted to receive the error signal, a transmitted port of the second sub-amplifier input hybrid coupler is coupled to an input of a third sub-amplifier of the plurality of sub-amplifiers, a coupled port of the second sub-amplifier input hybrid coupler is coupled to an input of a fourth sub-amplifier of the plurality of sub-amplifiers, and an isolated port of the second sub-amplifier input hybrid coupler is coupled to a load.

8. The amplifier error correction circuit of claim 1, wherein the output signal combining circuit comprises an output transmission line coupled between the first input and the output of the amplifier error correction circuit, wherein outputs of at least two of the sub-amplifiers are coupled to different places along the output transmission line.

9. The amplifier error correction circuit of claim 8, wherein the distance between the different places along the output transmission line is a quarter wavelength at the center frequency of an operating frequency band of the circuit, and/or the distance between the different places along the output transmission line causes a phase delay of substantially 90 degrees at the center frequency of the operating frequency band of the circuit.

10. The amplifier error correction circuit of claim 8, wherein:
segments of the output transmission line between the outputs of the sub-amplifiers have a same characteristic impedance, and supply voltages for the sub-amplifiers are increased along the output transmission line towards the output port; or
supply voltages for the sub-amplifiers are equal, and the characteristic impedance of segments of the output transmission line between the outputs of the sub-amplifiers decreases along the output transmission line towards the output port.

11. The amplifier error correction circuit of claim 8, wherein output currents of the sub-amplifiers along the output transmission line are weighted according to a window function.

12. The amplifier error correction circuit of claim 11, wherein the window function is bell-shaped and/or is any one of Dolph-Chebyshev, Gaussian, Binomial, Flamming or Blackman, or a combination thereof.

13. The amplifier error correction circuit of claim 8, wherein the output signal combining circuit comprises a first output signal hybrid coupler, wherein an input port of the first output signal hybrid coupler is coupled to the output transmission line such that the first output signal hybrid coupler is coupled between the output transmission line and the output of the amplifier error correction circuit, a transmitted port of the first output signal hybrid coupler is coupled to an output of a first sub-amplifier of the plurality of sub-amplifiers, a coupled port of the first output signal hybrid coupler is coupled to an output of a second sub-amplifier of the plurality of sub-amplifiers, and an isolated port of the first output signal hybrid coupler is coupled to the output of the amplifier error correction circuit.

14. The amplifier error correction circuit of claim 8, wherein the output signal combining circuit comprises a second output signal hybrid coupler, wherein an input port of the second output signal hybrid coupler is coupled to the first input, a transmitted port of the second output signal hybrid coupler is coupled to an output of a third sub-amplifier of the plurality of sub-amplifiers, a coupled port of the second output signal hybrid coupler is coupled to an output of a fourth sub-amplifier of the plurality of sub-amplifiers, and an isolated port of the second output signal hybrid coupler is coupled to the output transmission line such that the second output signal hybrid coupler is coupled between the first input and the output transmission line.

15. The amplifier error correction circuit of claim 1, wherein the output signal combining circuit comprises a second output signal hybrid coupler, wherein an input port of the second output signal hybrid coupler is coupled to the first input, a transmitted port of the second output signal hybrid coupler is coupled to an output of a first sub-amplifier of the plurality of sub-amplifiers, a coupled port of the second output signal hybrid coupler is coupled to an output of a second sub-amplifier of the plurality of sub-amplifiers, and an isolated port of the second output signal hybrid coupler is coupled to the output of the amplifier error correction circuit.

16.-20. (canceled)

21. An electronic device comprising an amplifier error correction circuit according to claim 1.

22. The electronic device according to claim 21, comprising a radio frequency transceiver, a wireless communication device, a user equipment, a mobile device, a base station or a radio network node.

23. The electronic device of claim 21, wherein the electronic device comprises an amplifier circuit configured to receive the input signal and to provide the output signal of an amplifier circuit to the first input.
